(19) United States
(12) Patent Application Publication
(10) Pub. No.: US 2020/0408593 A1
(43) Pub. Date: Dec. 31, 2020

(54) Vibration Sensor, Audio Device, and Method For Assembling Vibration Sensor

(71) Applicant: AAC ACOUSTIC TECHNOLOGIES (SHENZHEN) CO., LTD., Shenzhen (CN)

(72) Inventor: Jinyu Zhang, Shenzhen (CN)

(21) Appl. No.: 16/986,208

(22) Filed: Aug. 5, 2020

Related U.S. Application Data
(63) Continuation of application No. PCT/CN2019/093335, filed on Jun. 27, 2019.

(51) Int. Cl. G01H 11/06; H04R 19/04; B81B 7/00; B81B 7/02

(52) U.S. Cl. CPC G01H 11/06; H04R 19/04; B81B 2201/0257; B81B 7/02; B81B 7/007

(57) ABSTRACT

The present disclosure provides a vibration sensor, an audio device, and a method for assembling the vibration sensor. The vibration sensor includes a housing having an inner wall and an inner chamber, a gasket, an elastic film, and a MEMS chip having a back cavity; the gasket, the elastic film, and the MEMS chip received in the chamber; the gasket attached onto the inner wall, the elastic film attached onto one side of the gasket opposite to the inner wall, and the MEMS chip attached onto one side of the elastic film opposite to the gasket; a concave hole being defined in one side of the gasket facing the elastic film, the elastic film covering the concave hole, a through hole being defined in the elastic film and passing through the elastic film, and the through hole communicating the concave hole with the back cavity.

### FIELD OF THE PRESENT DISCLOSURE

The present disclosure relates to the field of microphone, and more particularly to a vibration sensor, an audio device, and a method for assembling a vibration sensor.

### DESCRIPTION OF RELATED ART

In related arts, vibration sensor generally includes a housing, a mounting plate attached to the housing, an elastic film attached to an upper side of the mounting plate, and a MEMS chip mounted on a lower side of the mounting plate and cooperatively forming a front cavity with the mounting plate. The mounting plate is provided with a through hole communicating the front cavity and the elastic film. Mass block vibrates up and down when external vibration signals are transmitted to the vibration sensor through a structure, causing change of the front cavity volume, and the gas pressure in the front cavity changes accordingly. The signal of pressure changing is picked up by the MEMS chip and converted into an electrical signal. However, the vibration sensor in the related art has the problem of high height and low sensitivity.

Therefore, it is necessary to provide a vibration sensor having lower height and higher sensitivity.

### SUMMARY OF THE PRESENT DISCLOSURE

The purpose of the present disclosure is to provide a vibration sensor having lower height and higher sensitivity.

In one aspect of the present invention, a vibration sensor includes a housing having an inner wall and an inner chamber surrounded by the inner wall, a gasket, an elastic film, and a MEMS chip having a back cavity; the gasket, the elastic film, and the MEMS chip are received in the inner chamber; the gasket is mounted on the inner wall, the elastic film is mounted on one side of the gasket opposite to the inner wall, and the MEMS chip is mounted on one side of the elastic film opposite to the gasket; a concave hole is defined in one side of the gasket facing the elastic film, and the elastic film covers the concave hole; and a through hole is defined in the elastic film and passing through the elastic film, and the through hole communicates with the concave hole and the back cavity.

Further, the concave hole passes from one side of the gasket facing the elastic film through one side of the gasket facing the inner wall.

Further, the housing includes a circuit board and an upper shell fixed on the circuit board, and the circuit board forms the inner wall.

Further, the vibration sensor also includes an integrated circuit chip received in the inner chamber, and the integrated circuit chip is electrically connected with the circuit board and the MEMS chip for processing vibration signals picked up by the MEMS chip.

Further, the MEMS chip is a MEMS microphone chip or a MEMS pressure sensor chip.

An audio device is also provided, which includes the vibration sensor as described above.

A method for assembling the vibration sensor is also provided, which includes the following operations:

mounting a gasket on a tooling having a protruding block, and inserting the protruding block into a concave hole defined in the gasket;

attaching an elastic film on a top surface of the gasket, and making the elastic film cover the concave hole;

mounting a MEMS chip on a top surface of the elastic film; and

transferring the gasket, the elastic film, and the MEMS chip out from the tooling and putting them into an inner chamber.

Further, the operation of transferring the gasket, the elastic film and the MEMS chip out from the tooling and putting them into the inner chamber is carried out as follows:

transferring the gasket, the elastic film, and the MEMS chip out from the tooling and putting them on a circuit board, and attaching the circuit board to a bottom surface of the gasket; and

mounting an upper shell on one side of the circuit board to allow the gasket, the elastic film, and the MEMS chip being accommodated in the inner chamber formed by the upper shell and the circuit board.

Further, before the operation of mounting the gasket on the tooling, the method also includes: mounting an integrated circuit chip on the top surface of the gasket.

The method also includes: electrically connecting the integrated circuit chip with the MEMS chip by a first connecting wire after the operation of mounting the MEMS chip on the top surface of the elastic film and before the operation of transferring the gasket, the elastic film and the MEMS chip out from the tooling and putting them into the inner chamber; and

electrically connecting the integrated circuit chip with the circuit board by a second connecting wire after the operation of transferring the gasket, the elastic film and the MEMS chip out from the tooling and mounting them on the circuit board.

Optionally, after the operation of transferring the gasket, the elastic film and the MEMS chip out from the tooling and mounting them on the circuit board, the method further includes:

mounting an integrated circuit chip on a top surface of the circuit board;

electrically connecting the integrated circuit chip with the MEMS chip by a first connecting wire; and

electrically connecting the integrated circuit chip with the circuit board by a second connecting wire.

The present disclosure has the advantages as follows. A gasket is attached to the inner wall of the housing, a concave hole is defined in the gasket, an elastic film is attached to the inner wall of the gasket opposite to the chamber, the elastic film covers the concave hole and is provided with a through hole communicating with the concave hole, and the back cavity of the MEMS chip communicates with the concave hole through the through hole, all of which improves the sensitivity of the vibration sensor. Besides, the height of the product is reduced as the volume of the front cavity is reduced, as a result of the MEMS chip replacing the mass block.

### BRIEF DESCRIPTION OF THE DRAWINGS

FIG. 1 is a schematic structural diagram of a vibration sensor according to the embodiments of the present disclosure;

FIG. 2 is an exploded view of the vibration sensor in FIG. 1;

FIG. 3 is a sectional view of FIG. 1 taken along line A-A;

FIG. 4 is a partial flow chart of a method for assembling the vibration sensor according to the embodiments of the present disclosure;

FIG. 5 is another partial flow chart of a method for assembling the vibration sensor according to the embodiments of the present disclosure.

In the drawings: 100, Vibration sensor; 1, housing; 2, Gasket; 3, Elastic film; 4, MEMS chip; 20, Concave hole; 30, Through holes; 11, Circuit board; 12, upper shell; 120, Inner chamber; 40, Concave cavity; 5, Integrated circuit chip; 6, Tooling; 61, Protruding block; 71, First connecting wire; 72, Second connecting wire.

### DETAILED DESCRIPTION OF THE EXEMPLARY EMBODIMENT

The present disclosure will be further explained with reference to the drawings and embodiments.

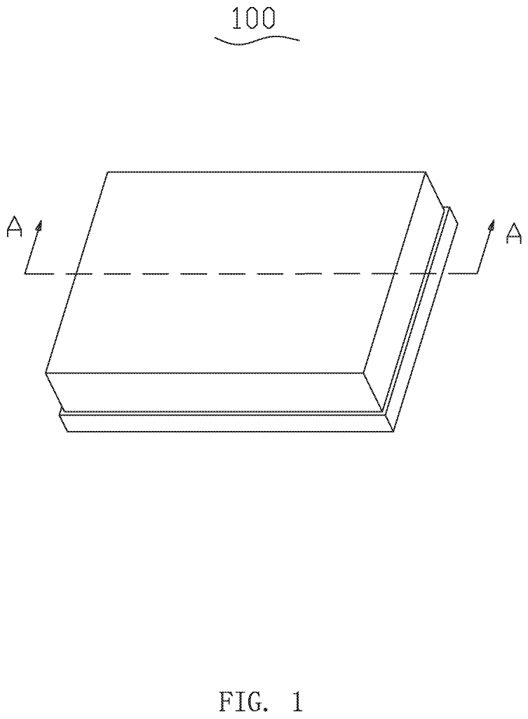

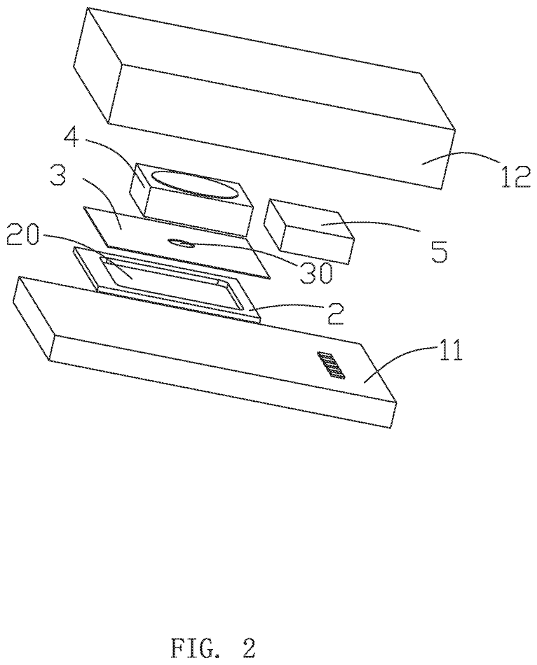

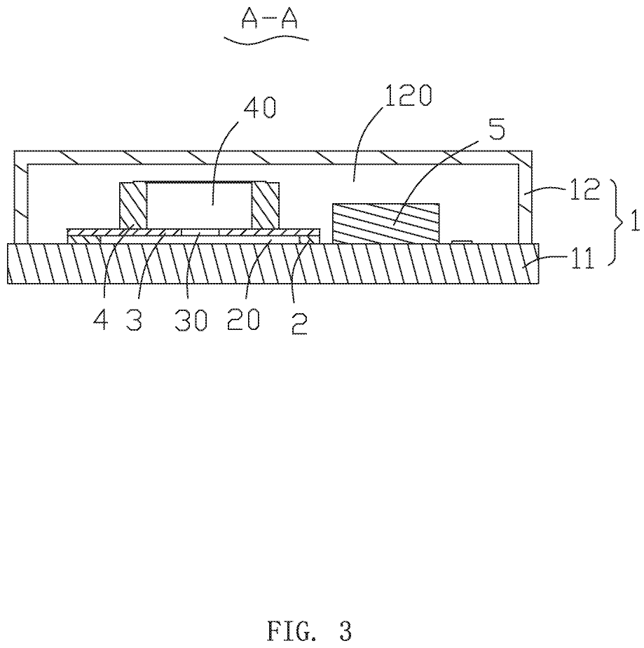

Referring to FIGS. 1 to 3, a vibration sensor 100 includes a housing 1 with an inner wall and an inner housing 120 surrounded by the inner wall, a gasket 2, an elastic film 3, and a MEMS chip 4 having a back cavity, the gasket 2, the elastic film 3, and the MEMS chip 4 are received in the inner housing 120. The gasket 2 is attached on the inner wall, the elastic film 3 is attached on one side of the gasket 2 opposite to the inner wall, the MEMS chip 4 is attached on one side of the elastic film 3 opposite to the gasket 2. A concave hole 20 is defined in one side of the gasket 2 facing the elastic film 3. The elastic film 3 covers the concave hole 20, and a through hole 30 passing through the elastic film 3 is defined in the elastic film 3. The through hole communicates the concave hole 20 with the back cavity 40.

The MEMS chip 4 is mounted on the upper side of the elastic film 3. The MEMS chip 4 vibrates up and down with the elastic film 3 when the external vibration signal is transmitted to the vibration sensor 100 through the structure, which causes change of the volume in the concave hole 20 and accordingly causes change of the gas pressure in the concave hole 20. The signal of the pressure changing is picked up by the MEMS chip 4 and converted into an electrical signal, so that the changed pressure signal may be picked up more easily by the MEMS chip 4, and the sensitivity of the vibration sensor 100 is improved. In addition, the height of the product is reduced as a result of MEMS chip 4 replacing the mass block.

Optionally, the concave hole 20 passes from one side of the gasket 2 facing the elastic film 3 through one side of the gasket 2 facing the inner wall. As such, the gasket 2 is fully utilized to increase the volume of the concave hole 20.

Optionally, the housing 1 includes a circuit board 11 and an upper shell 12 fixed on the circuit board 11, and the circuit board 11 forms the inner wall. upper shell. The upper shell 12 is mounted on the circuit board 11 to form the inner housing 120, and the upper shell covers the gasket 2, the elastic film 3, and the MEMS chip 4. The circuit board 11 is fully utilized to reduce the size of the vibration sensor 100.

Specifically, the inner housing 120 of the upper shell 12 is formed as a rear cavity of the vibration sensor 100, and the concave hole 20 is enclosed with the circuit board 11 to form a front cavity of the vibration sensor 100.

The concave hole 20 and the through hole 30 are both cylindrical, and it is optimized that the central axes of the concave hole 20 and the through hole 30 are collinear.

Optionally, the vibration sensor 100 also includes an integrated circuit chip 5 arranged in the housing 1, the integrated circuit chip 5 is electrically connected with both the circuit board 11 and the MEMS chip 4 for processing vibration signals picked up by the MEMS chip 4. The integrated circuit chip 5 may be attached onto the top surface of the gasket 2 or onto the top surface of the circuit board 11.

Optionally, the MEMS chip 4 is a MEMS microphone chip or a MEMS pressure sensor chip.

The present disclosure also provides an audio device (not shown in the figures), which includes the vibration sensor 100 as described above.

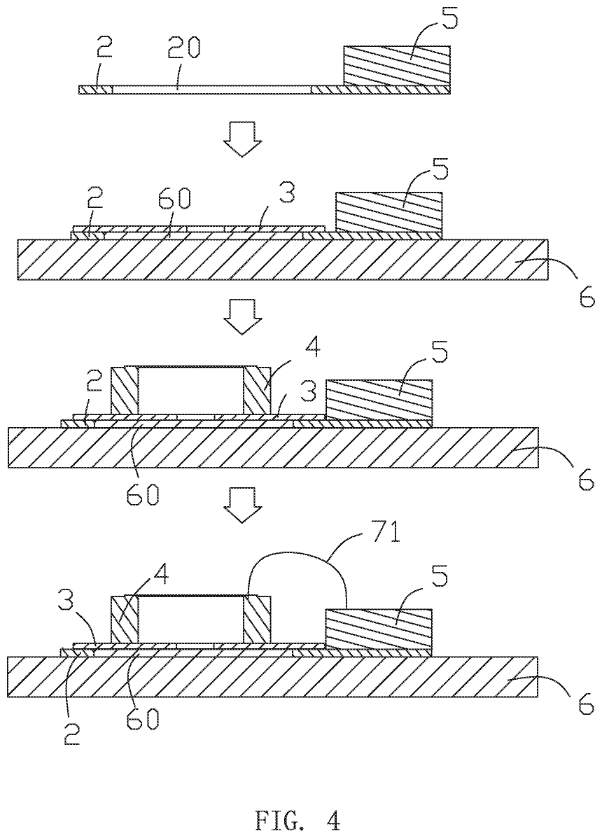

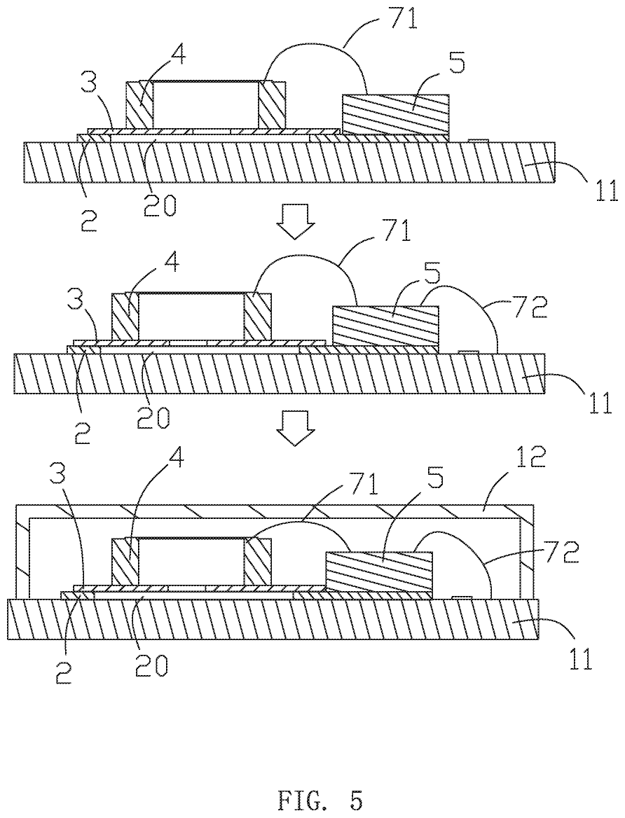

The present disclosure also provides a method for assembling. Please refer to FIG. 4 and FIG. 5, FIG. 5 shows the operations of the method after that in FIG. 4. The method includes the following operations:

The gasket 2 is mounted on a tooling 6 having a protruding block 61 and the protruding block 6 is inserted in the concave hole 20;

The elastic film 3 is attached to a top surface of the gasket 2 and covered the concave hole 20;

The MEMS chip 4 is mounted on a top surface of the elastic film 3; and

The gasket 2, the elastic film 3, and the MEMS chip 4 are transferred from the tooling 6 to the inner chamber 120 of the housing 1.

The elastic film 3 is supported by the protruding block 61 when being attached. The deformation of the elastic film 3 is avoided due to the support of the protruding block 61 when the MEMS chip 4 is mounted on the elastic film 3, thereby ensuring the structural stability during assembly.

Optionally, the elastic film 3 is adhered to the gasket 2 by gluing.

Optionally, the MEMS chip 4 is attached onto the elastic film 3 by gluing.

Optionally, the operation of transferring the gasket 2, the elastic film 3, and the MEMS chip 4 from the tooling 6 to the housing 1 is as follows:

The gasket 2, the elastic film 3, and the MEMS chip 4 are transferred out from the tooling 6 and mounted on the circuit board 11, and the circuit board 11 is attached to the bottom surface of the gasket 2;

and

The upper shell 12 is mounted on one side of the circuit board 11 to allow the gasket 2, the elastic film 3, and the MEMS chip 4 being accommodated in the inner chamber 120 formed by the upper shell 12 and the circuit board 11.

Optionally, before mounting the gasket 2 on the tooling 6, the method also includes: arranging the integrated circuit chip 5 on the top surface of the gasket 2;

After mounting the MEMS chip 4 on the top surface of the elastic film 3 and before transferring the gasket 2, the elastic film 3, and the MEMS chip 4 from the tooling 6 and mounting them in the housing 1, the method also includes: electrically connecting the integrated circuit chip 5 with the MEMS chip 4 by a first connecting wire 71; and

After transferring the gasket 2, the elastic film 3, and the MEMS chip 4 from the tooling 6 and mounting them on the circuit board 11, a second connecting wire 72 is electrically connected between the integrated circuit chip 5 and the circuit board 11.

Optionally, the integrated circuit chip 5 is arranged on the gasket 6 by gluing.

Optionally, the integrated circuit chip is ASIC chip.

An exemplary embodiment for assembling the vibration sensor 100 is provided, which includes the following operations:

The gasket 2 is mounted on the tooling 6 having the protruding block 61, and the protruding block 6 is inserted in the concave hole 20;

The integrated circuit chip 5 is arranged on the top surface of the gasket 2;

The elastic film 3 is attached to the top surface of the gasket 2 and covered the concave hole 20;

The MEMS chip 4 is mounted on the top surface of the elastic film 3;

The first connecting wire 71 is connected between the integrated circuit chip 5 and the MEMS chip 4;

The gasket 2, the elastic film 3, and the MEMS chip 4 are transferred from the tooling 6 and mounted on the circuit board 11, and the circuit board 11 is attached to the bottom surface of the gasket 2;

The second connecting wire 72 is connected between the integrated circuit chip 5 and the circuit board 11; and

The upper shell is mounted on one side of the circuit board 11 to cover the gasket 2, the elastic film 3, and the MEMS chip 4.

Another exemplary embodiment for assembling the vibration sensor 100 is provided, which includes the following operations:

The gasket 2 is mounted on a tooling 6 having a protruding block 61, and the protruding block 6 is inserted in the concave hole 20;

The integrated circuit chip 5 is arranged on a top surface of the gasket 2;

The elastic film 3 is attached to the top surface of the gasket 2 and covered the concave hole 20;

The gasket 2, the elastic film 3, and the MEMS chip 4 are transferred from the tooling 6 and mounted on the circuit board 11, the circuit board 11 is attached with the bottom surface of the gasket 2;

The integrated circuit chip 5 is mounted on the top surface of the circuit board 11;

The first connecting wire 71 is connected between the integrated circuit chip 5 and the MEMS chip 4;

The second connecting wire 72 is connected between the integrated circuit chip 5 and the circuit board 11; and

The upper shell is mounted on one side of the circuit board 11 to cover the gasket 2, the elastic film 3, and the MEMS chip 4.

According to the method for assembling the vibration sensor 100 provided by the present disclosure, the stability of mounting the elastic film 3 and the MEMS chip 4 is ensured through the support provided by the tooling 6 having the protruding block 61, when the elastic film 3 and the MEMS chip 4 are mounted on the gasket 2.

The description above is only an embodiment of the present disclosure. It should be pointed out here that for those of ordinary skill in the art, improvements can be made without departing from the inventive concept of the present disclosure, but these are all within the scope of the present disclosure.

What is claimed is:

1. A vibration sensor, comprising a housing having an inner wall and an inner chamber surrounded by the inner wall, a gasket, an elastic film, and a MEMS chip having a back cavity; the gasket, the elastic film, and the MEMS chip received in the chamber; the gasket attached onto the inner wall, the elastic film attached onto one side of the gasket opposite to the inner wall, and the MEMS chip attached onto one side of the elastic film opposite to the gasket; a concave hole being defined in one side of the gasket facing the elastic film, the elastic film covering the concave hole, a through hole being defined in the elastic film and passing through the elastic film, and the through hole communicating the concave hole with the back cavity.

2. The vibration sensor according to claim 1, wherein the concave hole passes from the side of the gasket facing the elastic film through one side of the gasket facing the inner wall.

3. The vibration sensor according to claim 1, wherein the chamber comprises a circuit board and an upper shell fixed on the circuit board, and the circuit board forms the inner wall.

4. The vibration sensor according to claim 1, wherein the vibration sensor further comprises an integrated circuit chip received in the inner chamber, the integrated circuit chip being electrically connected with the circuit board and the MEMS chip to process a vibration signal picked up by the MEMS chip.

5. The vibration sensor according to claim 1, wherein the MEMS chip is a MEMS microphone chip or a MEMS pressure sensor chip.

6. The vibration sensor according to claim 2, wherein the vibration sensor further comprises an integrated circuit chip received in the inner chamber, the integrated circuit chip being electrically connected with the circuit board and the MEMS chip to process a vibration signal picked up by the MEMS chip.

7. The vibration sensor according to claim 3, wherein the vibration sensor further comprises an integrated circuit chip received in the inner chamber, the integrated circuit chip being electrically connected with the circuit board and the MEMS chip to process a vibration signal picked up by the MEMS chip.

8. The vibration sensor according to claim 2, wherein the MEMS chip is a MEMS microphone chip or a MEMS pressure sensor chip.

9. The vibration sensor according to claim 3, wherein the MEMS chip is a MEMS microphone chip or a MEMS pressure sensor chip.

10. An audio device, comprising a vibration sensor; the vibration sensor comprising a housing having an inner wall and an inner chamber surrounded by the inner wall, a gasket, an elastic film, and a MEMS chip having a back cavity; the gasket, the elastic film, and the MEMS chip received in the chamber; the gasket attached onto the inner wall, the elastic film attached onto one side of the gasket opposite to the inner wall, and the MEMS chip attached onto one side of the elastic film opposite to the gasket; a concave hole being defined in one side of the gasket facing the elastic film, the elastic film covering the concave hole, a through hole being defined in the elastic film and passing through the elastic film, and the through hole communicating the concave hole with the back cavity.

11. The audio device according to claim 10, wherein the concave hole passes from the side of the gasket facing the elastic film through one side of the gasket facing the inner wall.

12. The audio device according to claim 10, wherein the chamber comprises a circuit board and an upper shell fixed on the circuit board, and the circuit board forms the inner wall.

13. The audio device according to claim 10, wherein the vibration sensor further comprises an integrated circuit chip received in the inner chamber, the integrated circuit chip being electrically connected with the circuit board and the MEMS chip to process a vibration signal picked up by the MEMS chip.

14. The audio device according to claim 10, wherein the MEMS chip is a MEMS microphone chip or a MEMS pressure sensor chip.

15. A method for assembling a vibration sensor, comprising:
mounting a gasket on a tooling having a protruding block, and inserting the protruding block in a concave hole defined in the gasket;
attaching an elastic film onto a top surface of the gasket, and making the elastic film cover the concave hole;
mounting a MEMS chip on a top surface of the elastic film; and
transferring the gasket, the elastic film, and the MEMS chip out from the tooling and mounting them in an inner chamber of a housing.

16. The method according to claim 15, wherein,
the operation of transferring the gasket, the elastic film, and the MEMS chip out from the tooling and mounting them in the inner chamber of the housing is carried out as follows:
transferring the gasket, the elastic film, and the MEMS chip out from the tooling and mounting them on a circuit board, and the circuit board being attached to a bottom surface of the gasket; and
mounting an upper shell on one side of the circuit board to allow the gasket, the elastic film, and the MEMS chip being accommodated in the inner chamber formed by the upper shell and the circuit board.

17. The method according to claim 16, wherein before the operation of mounting the gasket on the tooling, the method further comprises: mounting an integrated circuit chip on the top surface of the gasket;
electrically connecting the integrated circuit chip with the MEMS chip by a first connecting wire after the operation of mounting the MEMS chip on the top surface of the elastic film and before the operation of transferring the gasket, the elastic film, and the MEMS chip out from the tooling and mounting them in the inner chamber; and
electrically connecting the integrated circuit chip with the circuit board by a second connecting wire after the operation of transferring the gasket, the elastic film, and the MEMS chip out from the tooling and mounting them on the circuit board.

18. The method according to claim 16, wherein after the operation of transferring the gasket, the elastic film, and the MEMS chip out from the tooling and mounting them on the circuit board, the method further comprises:
mounting an integrated circuit chip on a top surface of the circuit board;
electrically connecting the integrated circuit chip with the MEMS chip by a first connecting wire; and
electrically connecting the integrated circuit chip with the circuit board by a second connecting wire.
